(19) United States
(12) Patent Application Publication
(10) Pub. No.: US 2023/0187436 A1
(43) Pub. Date: Jun. 15, 2023

(54) ELECTROSTATIC PROTECTION CIRCUIT AND CHIP

(71) Applicant: CHANGXIN MEMORY TECHNOLOGIES, INC., Hefei City (CN)

(72) Inventor: Qian XU, Hefei (CN)

(21) Appl. No.: 18/164,200

(22) Filed: Feb. 3, 2023

Related U.S. Application Data
(63) Continuation of application No. PCT/CN2021/136619, filed on Dec. 9, 2021.

(30) Foreign Application Priority Data
Jul. 5, 2021 (CN) 202110758321.8

(51) Int. Cl. H01L 27/02

(52) U.S. Cl. CPC H01L 27/0262

(57) ABSTRACT

An electro-static protection circuit and a chip are provided. The electro-static protection circuit includes an electro-static protection circuit and a control circuit. The electro-static protection circuit is located inside a protected chip and connected with the protected circuit. The control circuit is connected with the electro-static protection circuit, and is configured to output a high-level signal to the electro-static protection circuit to trigger the electro-static protection circuit to discharge an electro-static current when static electricity is generated on the protected chip, and output a low-level signal to the electro-static protection circuit to reduce a static leakage current of the electro-static protection circuit when the static electricity is not generated on the protected chip.

### CROSS-REFERENCE TO RELATED APPLICATIONS

The present disclosure is a US continuation application of International Application No. PCT/CN2021/136619, filed on Dec. 9, 2021, which claims the priority to Chinese patent application No. 202110758321.8, filed on Jul. 5, 2021. The disclosures of International Application No. PCT/CN2021/136619 and Chinese patent application No. 202110758321.8 are hereby incorporated by reference in their entireties.

### BACKGROUND

At present, the semiconductor manufacturing process is becoming more and more advanced. With the shorter channel length, shallower junction depth, the application of metal silicide, the application of Lightly Doped Drain (LDD) and the oxide layer are more and more thinner, which caused that the window of Electro-Static discharge (ESD) design becomes smaller and smaller, and the challenge of ESD protection design is becomes bigger and bigger. In order to protect integrated circuits from the harm of static electricity, electro-static protection is usually required for integrated circuits. However, the traditional electro-static protection circuit has some problems such as electric leakage.

### SUMMARY OF THE INVENTION

The embodiments of the present disclosure relate to the field of integrated circuit technology, in particular to an electro-static protection circuit and a chip.

According to a first aspect of the present disclosure, the present disclosure provides an electro-static protection circuit. The electro-static protection circuit includes an electro-static protection circuit and a control circuit.

The electro-static protection circuit is located inside a protected chip and connected with a protected circuit.

The control circuit is connected with the electro-static protection circuit, the control circuit is configured to output, when static electricity is generated on the protected chip, a high-level signal to the electro-static protection circuit to trigger the electro-static protection circuit to discharge an electro-static current, and output, when the static electricity is not generated on the protected chip, a low-level signal to the electro-static protection circuit to reduce a static leakage current of the electro-static protection circuit.

According to a second aspect of the present disclosure, the present disclosure provides a chip. The chip includes a protected circuit and the electro-static protection circuit described above.

### BRIEF DESCRIPTION OF THE DRAWINGS

FIG. 1 is a voltage-current characteristic diagram of Silicon Controlled Rectifier (SCR) in an ESD device.

FIG. 2 is a design window diagram of an ESD.

FIG. 3 is an equivalent circuit diagram of a Diode-string-triggered SCR (DTSCR).

FIG. 4 is a block diagram of a structure of an electro-static protection circuit provided in an embodiment of the present disclosure.

FIG. 5 is an equivalent circuit diagram of a DTSCR provided in an embodiment of the present disclosure.

FIG. 6 is an equivalent circuit diagram of an electro-static protection circuit provided in an embodiment of the present disclosure.

FIG. 7 is a block diagram of a structure of a chip provided in an embodiment of the present disclosure.

### DETAILED DESCRIPTION

The purpose of the present disclosure is to provide an electro-static protection circuit and a chip, which can solve the problem of electric leakage of the electro-static protection circuit in the traditional technology.

In the embodiments of present disclosure, the electro-static protection circuit includes an electro-static protection circuit and a control circuit. The control circuit is connected with the electro-static protection circuit. The control circuit is configured to detect whether the static electricity is generated on the protected chip. When the static electricity is generated on the protected chip, the control circuit outputs a high-level signal to the electro-static protection circuit as a trigger signal to trigger the electro-static protection circuit to discharge electro-static current, thereby performing electro-static protection on the protected chip. The control circuit may be specifically connected with the branch in which static leakage current exists in the electro-static protection circuit. When it is not detected that the static electricity is generated on the protected chip, the control circuit outputs a low-level signal to the branch circuit in which static leakage current exists in the electro-static protection circuit, so that the voltage drop at two ends of the branch in which static leakage current exists can be reduced when the static electricity is not generated on the protected chip, thereby reducing the static leakage current generated by the electro-static protection circuit. Electro-static protection circuit can not only perform electro-static protection on the protected chip, but also reduce its own leakage current.

For ease of understanding the present disclosure, a more complete description of the present disclosure will be given below with reference to the accompanying drawings. Embodiments of the present disclosure are given in the accompanying drawings. However, the present disclosure may be implemented in many different forms and is not limited to the embodiments described herein. Rather these embodiments are provided with a view to making the disclosure of the present application more thorough and comprehensive.

The reference numbers in the drawings are described in the following: 10: Electro-static protection circuit, 20: Protected circuit, 110: Control circuit, 120: Electro-static protection circuit, 111: Trigger sub-circuit, 112: Buffer sub-circuit, 121: Silicon controlled rectifier, 122: Diode string.

Unless otherwise defined, all technical and scientific terms used herein have the same meaning as would normally be understood by those skilled in the art of the present disclosure. Terms used herein in the description of the present disclosure are for the purpose of describing specific embodiments only and are not intended to limit the present disclosure.

It will be understood that the terms “first”, “second” and the like used herein may be used to describe various elements herein, but such elements are not limited by these terms. These terms are only used to distinguish the first element from another element. For example, without departing from the scope of the present disclosure, the first resistor may be referred to as the second resistor, and similarly, the second resistor may be referred to as the first resistor. Both the first resistor and the second resistor are resistors, but they are not the same resistor.

It is understood that “connection” in the following embodiments should be understood as “electrical connection”, “communication connection” and the like if electrical signals or data is transmitted between the connected circuits, sub-circuits, modules, units, etc.

As used herein, the singular forms of “a”, “an” and “said/the” may also include plural forms unless the context clearly indicates otherwise. It should also be understood that the terms “including/containing” or “having” and the like indicate the presence of the stated feature, entirety, step, operation, component, part, or combination thereof, but do not exclude the possibility of the presence or addition of one or more other features, entireties, steps, operations, components, parts, or combination thereof. Meanwhile, the term “and/or” as used in this description includes any and all combinations of related listed items.

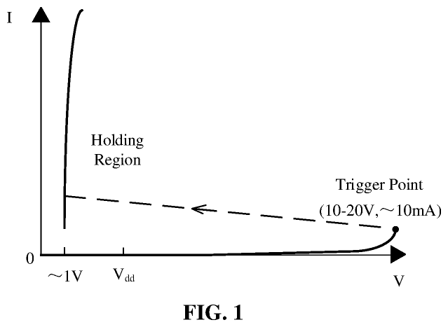

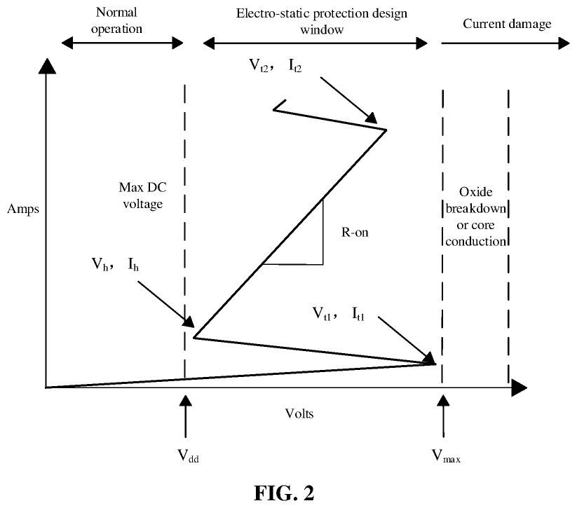

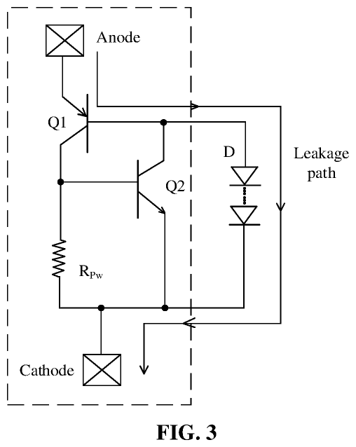

At present, the ESD devices used in the electro-static protection of integrated circuits usually include diodes, Metal-Oxide-Semiconductor (MOS) Field-Effect Transistors and Silicon Controlled Rectifier (SCR) and so on. However, the conventional SCR has high trigger voltage and low holding voltage, and is easy to latch-up, so it is not suitable for electro-static protection of Dynamic Random Access Memory (DRAM) products. The voltage-current characteristic of a conventional SCR is shown in FIG. 1, which is deviated from the design window of ESD as shown in FIG. 2. In order to apply SCR to the electro-static protection of DRAM products, the traditional technology uses diode-string-triggered silicon controlled rectifier (DTSCR) to replace SCR. The equivalent circuit diagram of DTSCR is shown in FIG. 3, which includes diode string D and conventional SCR (the circuit diagram in the dashed box is the equivalent circuit diagram of SCR). However, DTSCR has leakage problem in the branch where diode string D is located, and the leakage path is shown in the arrow direction in FIG. 3.

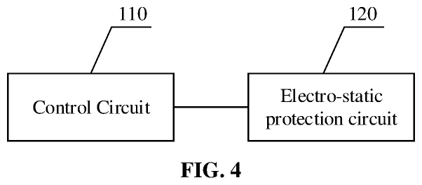

Referring to FIG. 4, FIG. 4 is a block diagram of a structure of an electro-static protection circuit provided in an embodiment of the present disclosure. The electro-static protection circuit includes a control circuit 110 and an electro-static protection circuit 120. The electro-static protection circuit 120 is located inside a protected chip (not shown in FIG. 1), and the electro-static protection circuit 120 is connected with the protected circuit (not shown in FIG. 1). The control circuit 110 is connected with the electro-static protection circuit 120. The control circuit 110 is configured to output a high-level signal to the electro-static protection circuit 120 to trigger the electro-static protection circuit 120 to discharge the electro-static current when static electricity is generated on the protected chip, and output a low-level signal to the electro-static protection circuit 120 to reduce a static leakage current of the electro-static protection circuit 120 when the static electricity is not generated on the protected chip.

In some embodiments of the disclosure, the high-level signal may be a signal of high voltage level, and the low-level signal may be a signal of low voltage level. Herein, the specific voltage range of the high voltage level and the specific voltage range of the low voltage level can be determined based on requirements of the practical application, which are not limited in the embodiments of the disclosure. For example, high voltage level may be a state that higher than or equal to the supply voltage, and the low voltage level may be a state that lower than or equal to the ground voltage.

In some embodiments, the protected chip may be a logic chip, an analog chip, a memory chip, or the like. The protected chip may be specifically a DRAM chip when the protected chip is a memory chip. The protected circuit may be a functional circuit inside the protected chip. The electro-static protection circuit 120 is located inside the protected chip, and the electro-static protection circuit 120 is connected with the protected circuit. The control circuit 110 is connected with the electro-static protection circuit 120. The control circuit 110 is configured to detect whether the static electricity is generated on the protected chip. When the static electricity is not generated on the protected chip, the control circuit 110 outputs a high-level signal to the electro-static protection circuit 120 as a trigger signal to trigger the electro-static protection circuit 120 to discharge electro-static current, thereby performing electro-static protection on the protected chip. The control circuit 110 may be specifically connected with the branch in which static leakage current exists in the electro-static protection circuit 120. When it is not detected that the static electricity is generated on the protected chip, the control circuit 110 outputs a low-level signal to the branch circuit in which static leakage current exists in the electro-static protection circuit 120, so that the voltage drop at two ends of the branch in which static leakage current exists can be reduced when the static electricity is not generated on the protected chip, thereby reducing the static leakage current generated by the electro-static protection circuit 120. Electro-static protection circuit in the embodiments in the present disclosure can not only perform electro-static protection on the protected chip, but also reduce its own leakage current.

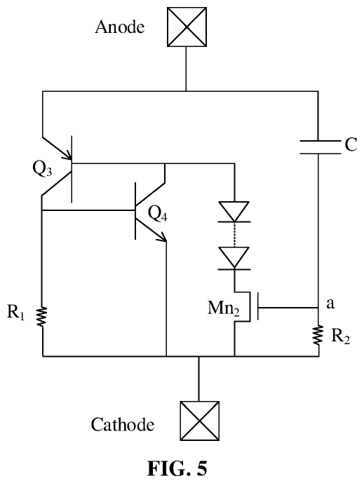

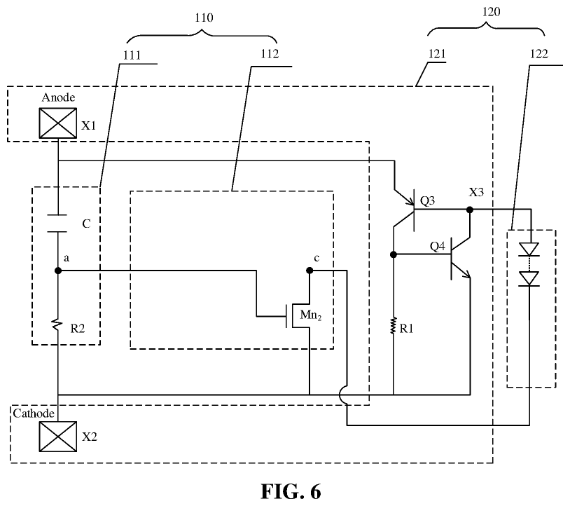

In one embodiment, referring to FIG. 5 and FIG. 6, the electro-static protection circuit 120 includes a silicon controlled rectifier 121 and a diode string 122. The silicon controlled rectifier 121 is provided with an anode X1, a cathode X2, and a trigger end X3. The control circuit 110 is connected between the anode X1 and the cathode X2 of the silicon controlled rectifier 121. The SCR 121 may be any SCR or modified device well known to those skilled in the art.

The diode string 122 includes a plurality of diodes connected in series. These diodes are connected end to end in turn. The cathode and anode from the two diodes at the head and the end are respectively used as the cathode and anode of the diode string 122. The number of diodes may be set according to requirements. The anode of the diode string 122 is connected with the trigger end X3 of the SCR 121, and the cathode of the diode string 122 is connected with the control circuit 110. When the static electricity is generated on the protected chip, the control circuit 110 outputs the high-level signal to the cathode of the diode string 122 as a trigger signal, and triggers, through the diode string 122, the silicon controlled rectifier 121 to operate, thereby discharging the electro-static current generated when static electricity is generated on the protected chip. In some embodiments, when static electricity is generated on the protected chip, the voltage difference between the two ends of the diode string 122 is greater than the threshold voltage at which the diode string 122 is conductive. The diode string 122 is firstly conductive, then the SCR is triggered, and then the SCR quickly passes a large current, thereby releasing static electricity. Since the conduction voltage required to conduct the diode string 122 is low, there is a low trigger voltage. When the static electricity is not generated in the protected chip, the control circuit 110 outputs a low-level signal to the cathode of the diode string 122, which greatly reduces the voltage drop at two ends of the diode string 122, thereby reducing the leakage current of the branch where the diode string 122 is located.

In this embodiment, DTSCR is used for electro-static protection of the protected chip, so that the silicon controlled rectifier 121 in the electro-static protection circuit has the advantages of low trigger voltage, adjustable trigger voltage, and a holding voltage greater than the power supply voltage of the protected chip, thereby avoiding the occurrence of latch-up and having high electro-static protection capability. The electro-static protection circuit is particularly suitable for electro-static protection of a chip with low operating voltage in an advanced manufacturing process, and the protected chip may be a DRAM chip. Furthermore, the conventional DTSCR is improved, and when the static electricity is not generated on the protected chip, the control circuit 110 outputs a low-level signal to the cathode of the diode string 122 in the DTSCR to reduce the voltage drop at two ends of the diode string 122, thereby reducing the leakage current of the DTSCR.

In one embodiment, the trigger voltage of the SCR 121 increases with increase of the number of diodes. The amplitude of trigger voltage may be adjusted according to the operating voltage of the protected chip, and the trigger voltage of the SCR 121 is proportional to the number of diodes, so the number of diodes in the diode string 122 may be set according to the operating voltage of the protected chip. When the protected chip is a DRAM chip, the operating voltage may be 1.1 V or 1.2 V, and the number of diodes may be set to be 2 or 3 according to the operating voltage, thereby meeting the requirements of the DRAM chip. Of course, the number of diodes in the diode string 122 may be set to be other values according to practical requirement in order to meet the requirements of operating voltages of other chip.

In one embodiment, the trigger voltage of the SCR 121 is less than the maximum voltage of an electro-static protection design window. Referring to FIG. 2, the maximum value Vmax of the ESD design window may be set according to the operating voltage of the protected chip, and then the trigger voltage Vt1 of the SCR 121 may be set less than the maximum value Vmax of the ESD design window, so that the trigger point (Vt1, It1) of the SCR 121 is within the ESD design window.

In one embodiment, the holding voltage of the SCR 121 is greater than the power supply voltage of the protected chip. Still referring to FIG. 2, the minimum value of the electro-static protection design window may be set to the power supply voltage Vdd of the protected chip, and further the holding voltage Vh of the SCR 121 may be set to be greater than the power supply voltage Vdd of the protected chip, so that the holding point (Vh, Ih) of the SCR is within the electro-static protection design window. The holding voltage of the SCR 121 being greater than the power supply voltage of the protected chip may avoid the occurrence of latch-up.

In one embodiment, referring to FIG. 6, the equivalent circuit of the SCR 121 includes a first triode Q3, a second triode Q4, and a first resistor R1. An emitter of the first triode Q3 is the anode X1 of the silicon controlled rectifier 121. A base of the first triode Q3 is connected with the anode of the diode string 122 and a collector of the second triode Q4. A collector of the first triode Q3 is connected with a base of the second triode Q4 and one end of the first resistor R1. An emitter of the second triode Q4 being connected with the other end of the first resistor R1 serves as the cathode X2 of the silicon controlled rectifier 121. In this embodiment, the base of the first triode Q3 being connected with the collector of the second triode Q4 serves as the trigger end X3 of the silicon controlled rectifier 121.

Optionally, the first triode Q3 is a PNP triode, and the second triode Q4 is an NPN triode.

In this embodiment, when the static electricity is generated on the protected chip, the control circuit 110 outputs a high-level signal to the cathode of the diode string 122, so that the diode string 122 is firstly conductive, and then the first triode Q3 and the second triode Q4 in the silicon controlled rectifier 121 are conductive successively, thus forming a plurality of electro-static discharge channels to discharge the electro-static current generated by the protected chip. Specifically, when static electricity is generated on the protected chip, the voltage difference between the two ends of the diode string 122 is greater than the threshold voltage at which the diode string 122 is conductive. The diode string 122 is firstly conductive, then the first triode Q3 and the second triode Q4 in the SCR are conductive successively, and then the SCR quickly passes a large current, thereby releasing static electricity. Since the conduction voltage required to conduct the diode string 122 is low, there is a low trigger voltage.

In one embodiment, still referring to FIG. 6, the control circuit 110 includes a trigger sub-circuit 111 and a buffer sub-circuit 112. The trigger sub-circuit 111 is connected between the anode X1 and the cathode X2 of the silicon controlled rectifier 121, and is configured to generate a high-level signal when the static electricity is generated on the protected chip and generating a low-level signal when the static electricity is not generated on the protected chip. The buffer sub-circuit 112 is connected between the cathode X2 of the silicon controlled rectifier 121 and the cathode of the diode string 122, and an input end of the buffer sub-circuit 112 is connected with the output end of the trigger sub-circuit 111.

In some embodiments, the trigger sub-circuit 111 generates a high-level signal when the static electricity is generated on the protected chip. After receiving the high-level signal output by the trigger sub-circuit 111, the input end of the buffer sub-circuit 112 outputs the high-level signal to the diode string 122. The trigger sub-circuit 111 generates a low-level signal when the static electricity is not generated on the protected chip. After receiving the low-level signal output by the trigger sub-circuit 111, the input end of the buffer sub-circuit 112 outputs the low-level signal to the diode string 122.

In one embodiment, the trigger sub-circuit 111 includes a second resistor R2 and a capacitor C. One end of the capacitor C is connected with the anode X1 of the silicon controlled rectifier 121. The other end of the capacitor C is connected with one end of the second resistor R2 and serves as the output end of the trigger sub-circuit 111. The other end of the second resistor R2 is connected with the cathode X2 of the silicon controlled rectifier 121.

In this embodiment, the trigger sub-circuit 111 is an RC circuit for detecting whether static electricity is generated on the protected chip. When the static electricity is generated on the protected chip, transient current passes the RC circuit, which makes the capacitor C conductive, thereby pulling the potential of the output end of the trigger sub-circuit 111 to be the same as the potential of the cathode X2 of the silicon controlled rectifier 121. When static electricity is not generated on the protected chip, the capacitor C in the RC circuit is not conductive, which is equivalent to a short circuit. The potential of the output end of the trigger sub-circuit 111 is pulled to the same as the potential of the anode X1 of the silicon controlled rectifier 121 through the second resistor R2.

In one embodiment, the buffer sub-circuit 112 includes an NMOS transistor Mn2. The source of the NMOS transistor Mn2 is connected with the cathode X2 of the silicon controlled rectifier 121, the gate of the PMOS transistor Mp2 is connected with the output end of the trigger sub-circuit 111, and the drain of the PMOS transistor Mp2 is connected with the cathode of the diode string 122.

In this embodiment, when static electricity is generated on the protected chip, the trigger sub-circuit 111 outputs a high-level signal to the input end of the buffer sub-circuit 112. In FIG. 6, the potential of point a is high, so that the NMOS transistor Mn2 is conductive. The potential of point c is high, i.e., the buffer sub-circuit 112 outputs a high-level signal to the cathode of the diode string 122, and the diode string 122 conducts forward, which in turn triggers the silicon controlled rectifier 121 to discharge the electro-static current. When the static electricity is not generated on the protected chip, the trigger sub-circuit 111 outputs a low-level signal to the input end of the buffer sub-circuit 112. In FIG. 6, the potential of point a is low, so that the NMOS transistor Mn2 is turned off. The potential of point c is low, so that the buffer sub-circuit 112 outputs a low-level signal to the cathode of the diode string 122, thereby reducing the voltage drop at two ends of the diode string 122 and cutting off the diode string 122, thus greatly reducing the leakage current.

The present disclosure also provides a chip. The chip includes a protected circuit and an electro-static protection circuit in any one of the above embodiments. The electro-static protection circuit can discharge the electro-static current when static electricity is generated on the chip to ensure that the protected circuit is not damaged, and the static leakage current of the electro-static protection circuit itself is small or even zero, so that the chip loss will not be increased when static electricity is not generated on the chip.

In one embodiment, the protected circuit includes a power supply end (VDD), a ground end (VSS) and a signal transmission end. The electro-static protection circuit is connected between any two ends of the power supply end, the ground end and the signal transmission end to perform electro-static protection on the protected circuit. The signal transmission end of the protected circuit may include an input end (Input) and an output end (Output).

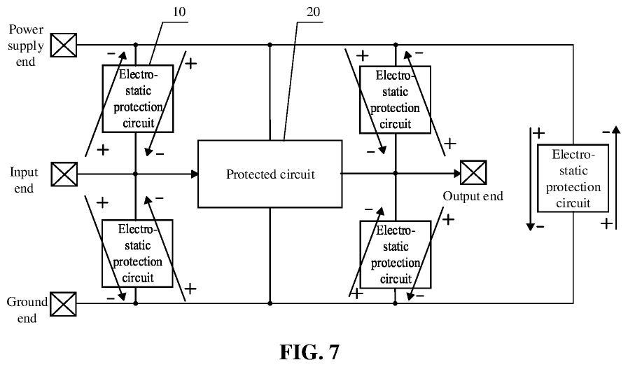

In one embodiment, referring to FIG. 7, the chip includes a plurality of electro-static protection circuits 10. The electro-static protection circuits 10 are connected between the power supply end and the ground end, between the power supply end and the signal transmission end, and between the ground end and the signal transmission end of the protected circuit 20. The electro-static protection circuit 10 may be specifically connected between the power supply end and the input end, between the input end and the ground end, between the power supply end and the output end, between the output end and the ground end, and between the power supply end and the ground end. Furthermore, the anode and the cathode of the electro-static protection circuit 10 may be connected in reverse to discharge the reverse electro-static current, which can be arranged according to practical requirements. In this embodiment, reverse connection is relative to forward connection. For example, when the forward connection represents that the anode of the electro-static protection circuit 10 is connected with the power supply end of the protected circuit 20 and the cathode of the electro-static protection circuit 10 is connected with the ground end of the protected circuit 20, the reverse connection represents that the anode of the electro-static protection circuit 10 is connected with the ground end of the protected circuit 20 and the cathode of the electro-static protection circuit 10 is connected with the power supply end of the protected circuit 20.

In one embodiment, the chip may include a logic chip, an analog signal or memory chip, etc.

In one embodiment, the chip may include a DRAM chip.

In the description of this description, the description of the reference terms “some embodiments”, “other embodiments”, “desirable embodiments”, and the like means that specific features, structures, materials, or features described in combination with the embodiment or example are included in at least one embodiment or example of the present disclosure. In the description, the schematic description of the above terms does not necessarily refer to the same embodiments or examples.

The technical features of the above embodiments may be arbitrarily combined, and all possible combinations of the technical features of the above embodiments are not described in order to make the description concise. However, as long as there is no contradiction in the combinations of these technical features, they should be considered as the scope described in the description.

The above embodiments are merely illustrative of several embodiments of the present disclosure, and the description thereof is more specific and detailed but is not therefore to be construed as limiting the patent scope of the present disclosure. It should be noted that a number of modifications and improvements may be made to those of ordinary skill in the art without departing from the concept of the present disclosure, which fall within the scope of protection of the present disclosure. Therefore, the scope of protection of the patent application shall be subject to the attached claims.

1. An electro-static protection structure comprising:
an electro-static protection circuit, wherein the electro-static protection circuit is located inside a protected chip and connected with a protected circuit; and
a control circuit, wherein the control circuit is connected with the electro-static protection circuit, the control circuit is configured to output, when static electricity is generated on the protected chip, a high-level signal to the electro-static protection circuit to trigger the electro-static protection circuit to discharge an electro-static current, and output, when the static electricity is not generated on the protected chip, a low-level signal to the electro-static protection circuit to reduce a static leakage current of the electro-static protection circuit.

2. The electro-static protection structure of claim 1, wherein the electro-static protection circuit comprises:
an silicon controlled rectifier, provided with an anode, a cathode and a trigger end, wherein the control circuit is connected between the anode and the cathode of the silicon controlled rectifier, and
a diode string, wherein the diode string comprises a plurality of diodes connected in series, an anode of the diode string is connected with the trigger end of the silicon controlled rectifier, and a cathode of the diode string is connected with the control circuit, wherein when the static electricity is generated on the protected chip, the control circuit outputs the high-level signal to the cathode of the diode string to trigger the silicon controlled rectifier to discharge an electro-static current, and when the static electricity is not generated on the protected chip, the control circuit outputs the low-level signal to the cathode of the diode string to reduce a voltage drop at two ends of the diode string.

3. The electro-static protection structure of claim 2, wherein,
a trigger voltage of the silicon controlled rectifier increases with increase of a number of diodes.

4. The electro-static protection structure of claim 2, wherein a number of diodes is 2 or 3.

5. The electro-static protection structure of claim 2, wherein,
a trigger voltage of the silicon controlled rectifier is less than a maximum voltage of an electro-static protection design window.

6. The electro-static protection structure of claim 2, wherein,
a holding voltage of the silicon controlled rectifier is greater than a power supply voltage of the protected chip.

7. The electro-static protection structure of claim 3, wherein,
an equivalent circuit of the silicon controlled rectifier comprises a first triode, a second triode and a first resistor, an emitter of the first triode is the anode of the silicon controlled rectifier, a base of the first triode is connected with the anode of the diode string and a collector of the second triode, a collector of the first triode is connected with a base of the second triode and one end of the first resistor, and an emitter of the second triode is connected with the other end of the first resistor and serves as the cathode of the silicon controlled rectifier.

8. The electro-static protection structure of claim 7, wherein the first triode is a PNP triode and the second triode is an NPN triode.

9. The electro-static protection structure of claim 7, wherein the control circuit comprises:
a trigger sub-circuit, wherein the trigger sub-circuit is connected between the anode and the cathode of the silicon controlled rectifier, and is configured to generate a high-level signal when the static electricity is generated on the protected chip, and generate a low-level signal when the static electricity is not generated on the protected chip; and
a buffer sub-circuit, wherein the buffer sub-circuit is connected between the cathode of the silicon controlled rectifier and the cathode of the diode string, and an input end of the buffer sub-circuit is connected with an output end of the trigger sub-circuit.

10. The electro-static protection structure of claim 9, wherein the trigger sub-circuit comprises a second resistor and a capacitor, one end of the capacitor is connected with the anode of the silicon controlled rectifier, the other end of the capacitor is connected with one end of the second resistor and serves as the output end of the trigger sub-circuit, and the other end of the second resistor is connected with the cathode of the silicon controlled rectifier.

11. The electro-static protection structure of claim 9, wherein the buffer sub-circuit comprises an N-Metal Oxide Semiconductor (NMOS) transistor, a source of the NMOS transistor is connected with the cathode of the silicon controlled rectifier, a gate of the NMOS transistor is connected with the output end of the trigger sub-circuit, and a drain of the NMOS transistor is connected with the cathode of the diode string.

12. A chip comprising a protected circuit and an electro-static protection circuit, wherein the electro-static protection circuit comprises:
an electro-static protection circuit, wherein the electro-static protection circuit is located inside a protected chip and connected with a protected circuit; and
a control circuit, wherein the control circuit is connected with the electro-static protection circuit, the control circuit is configured to output, when static electricity is generated on the protected chip, a high-level signal to the electro-static protection circuit to trigger the electro-static protection circuit to discharge an electro-static current, and output, when the static electricity is not generated on the protected chip, a low-level signal to the electro-static protection circuit to reduce a static leakage current of the electro-static protection circuit.

13. The chip of claim 12, wherein the protected circuit comprises a power supply end, a ground end and a signal transmission end, and the electro-static protection circuit is connected between any two of the power supply end, the ground end and the signal transmission end to perform electro-static protection on the protected circuit.

14. The chip of claim 13, wherein the chip comprises a plurality of the electro-static protection circuits, and the electro-static protection circuits are connected between the power supply end and the ground end, between the power supply end and the signal transmission end, and between the ground end and the signal transmission end.

15. The chip of claim 12, wherein the electro-static protection circuit comprises:
an silicon controlled rectifier, provided with an anode, a cathode and a trigger end, wherein the control circuit is connected between the anode and the cathode of the silicon controlled rectifier, and
a diode string, wherein the diode string comprises a plurality of diodes connected in series, an anode of the diode string is connected with the trigger end of the silicon controlled rectifier, and a cathode of the diode string is connected with the control circuit, wherein when the static electricity is generated on the protected chip, the control circuit outputs the high-level signal to the cathode of the diode string to trigger the silicon controlled rectifier to discharge an electro-static current, and when the static electricity is not generated on the protected chip, the control circuit outputs the low-level signal to the cathode of the diode string to reduce a voltage drop at two ends of the diode string.

16. The chip of claim 15, wherein,
a trigger voltage of the silicon controlled rectifier increases with increase of a number of diodes.

17. The chip of claim 15, wherein a number of diodes is 2 or 3.

18. The chip of claim 15, wherein,
a trigger voltage of the silicon controlled rectifier is less than a maximum voltage of an electro-static protection design window.

19. The chip of claim 15, wherein,
a holding voltage of the silicon controlled rectifier is greater than a power supply voltage of the protected chip.

20. The chip of claim 16, wherein,
an equivalent circuit of the silicon controlled rectifier comprises a first triode, a second triode and a first resistor, an emitter of the first triode is the anode of the silicon controlled rectifier, a base of the first triode is connected with the anode of the diode string and a collector of the second triode, a collector of the first triode is connected with a base of the second triode and one end of the first resistor, and an emitter of the second triode is connected with the other end of the first resistor and serves as the cathode of the silicon controlled rectifier.
